(19) United States
(12) Patent Application Publication
(10) Pub. No.: US 2009/0130850 A1
(43) Pub. Date: May 21, 2009

(54) Semiconductor Devices and Method of Fabricating the Same

(76) Inventor: Kang Hyun LEE, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/265,654

(22) Filed: Nov. 5, 2008

(30) Foreign Application Priority Data
Nov. 16, 2007 (KR) 10-2007-0117288

(51) Int. Cl. H01L 21/311

(52) U.S. Cl. 438/694; 257/E21.249

(57) ABSTRACT

A method of fabricating a semiconductor device is provided. A contact hole with a finer width can be formed by solving an exposure limit of KrF exposure apparatuses. The fabrication method includes forming a first insulation layer on a substrate; forming a photoresist pattern on the first insulation layer; forming a second insulation layer covering the photoresist pattern; forming a second insulation layer spacer in a sidewall of the photoresist pattern by etching the second insulation layer; forming a contact hole by etching the first insulation layer using the photoresist pattern and the second insulation layer spacer as a mask; removing the photoresist pattern; and removing the second insulation layer spacer. A contact hole with a finer width can be formed using a KrF exposure apparatus, and furthermore, contact resistance can be lowered and device characteristics can be improved

The present application claims priority under 35 U.S.C. 119 and 35 U.S.C. 365 to Korean Patent Application No. 10-2007-0117288 (filed on Nov. 16, 2007), which is hereby incorporated by reference in its entirety.

### BACKGROUND

### Description of the Related Art

A photolithography process is a necessary process in fabricating semiconductor devices. The process generally involves evenly covering a photoresist layer on a wafer, performing an exposure process using a photo mask corresponds to a given layout, and developing an exposed photoresist layer to form the photoresist layer in a pattern of specific shape.

Semiconductor photolithography technology used in the photolithography process performed in fabricating the semiconductor device provides a precise mask design. Accordingly the amount of light projected through the mask can be appropriately controlled.

An increasingly higher integration tendency of recent semiconductor devices uses more detailed and finer design rules and brings about a relatively smaller line width in the photoresist pattern. However, technical limits such as reinforcement interference of light and limits of the exposure apparatus, etc., may cause serious difficulty in forming a finer pattern such as a contact hole. In particular, in developing products of 130 nm and 90 nm line widths using a KrF exposure apparatus, it is difficult to get a desired line width due to tight process margins.

FIG. 1 shows a contact hole formed through a photo process using a conventional KrF exposure apparatus. FIG. 2 shows a contact hole formed through a conventional polymer rich process.

Referring to FIG. 1, a plurality of contact holes 20 are formed with a given size in an interlayer insulation film 10.

In using the KrF exposure apparatus, the process margin is not good, and so a critical dimension (CD) width as an upper diameter size of the contact holes 20 becomes wide, and as shown in area “A”, a gap with an adjacent contact hole 20 becomes smaller. Thus, there may be difficulty to stack layers afterward.

To improve that, etching using a polymer rich process is performed to reduce the upper CD width. Therefore, the upper CD width is reduced, and the spacer/distance between the contact holes 20 becomes wide, thereby obtaining sufficient margin. The polymer rich process forms a polymer in etching using C4F8, C3F8, C2F6, C5F8, etc., as the etching gas, and to prevent an upper CD width from becoming wider by forming contact hole 20 in a slanted shape with a slope.

However, the upper CD width of the contact hole 20 is reduced, but a slope within the contact hole 20 as a trade-off may be excessive. Thus, the bottom CD width of the contact hole 20 becomes smaller, as shown in area “B” of the drawing. Thus, there may be a problem in that contact resistance characteristics of the contact hole 20 may be too high.

The process margin is improved when a photo process is performed by replacing the KrF exposure apparatus with an ArF exposure apparatus, but the cost is relatively high, and there may be difficulties in the production.

### SUMMARY

Embodiments of the invention provide a method of fabricating a semiconductor device, which is capable of forming a contact hole with a finer width by solving an exposure limit of a KrF exposure apparatus (e.g. 130 nm or less).

According to an embodiment of the invention, a method of fabricating a semiconductor device comprises forming a first insulation layer on a substrate, forming a photoresist pattern on the first insulation layer, forming a second insulation layer covering the photoresist pattern, forming a second insulation layer spacer in a sidewall of the photoresist pattern by etching the second insulation layer, forming a contact hole by etching the first insulation layer using the photoresist pattern and the second insulation layer spacer as a mask, removing the photoresist pattern and removing the second insulation layer spacer.

As described above, according to embodiments of the invention, a contact hole with a finer width can be formed using a KrF exposure apparatus, and furthermore, contact resistance can be lowered, thereby improving device characteristics.

In addition, process margin can be realized by using a KrF exposure apparatus of low price, and thus, the occurrence of defects is reduced, and the manufacturing cost is lessened. Further, research development and apparatus replacement expenses associated with ArF photolithography equipment can be saved as it is not necessary to develop a new exposure apparatus or use an ArF exposure apparatus of relatively high price.

### BRIEF DESCRIPTION OF THE DRAWINGS

FIG. 1 shows a contact hole formed through a photo process using a conventional KrF exposure apparatus.

FIG. 2 shows a contact hole formed through a conventional polymer rich process.

FIGS. 3 to 7 are sectional views illustrating an exemplary process of fabricating a semiconductor device according to embodiments of the invention.

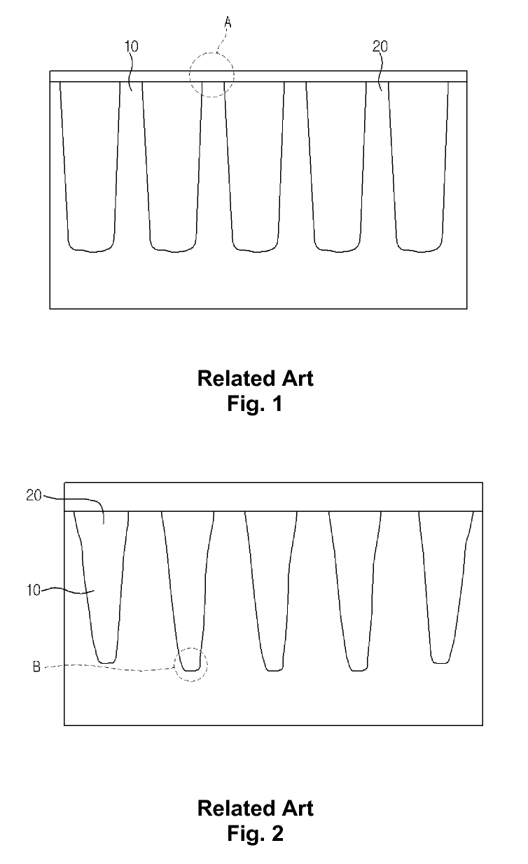

### DETAILED DESCRIPTION OF THE EMBODIMENTS

Hereinafter, a semiconductor device and a fabrication method thereof are described in detail, referring to the accompanied drawings. Components may be added, deleted or changed according to other embodiments as will be understood by those skilled in the art without deviating from the spirit of the invention.

Hereinafter, an expression to be a “first”, a “second”, etc., does not limit members, but instead, generally divides individual members of a group that includes at least two members. Therefore, it is apparent that the expression to be “first,” “second”, etc., refers to one (or more) of a plurality of members. Each member may be selectively or alternatively used. The size, measurement, of respective components in the accompanying drawings may be enlarged for facilitating an understanding of the invention. The measurement ratio of respective components described herein may be different from an actual measurement ratio. In the description, when each layer (film), an area, a pattern or structures are described as being formed “on/above/over/upper” or “down/below/under/lower” another layer (film), area, pattern or structure(s), each such layer (film), area, pattern or structure(s) may be in direct contact with the other layer (film), area, pattern or the structure(s), or one or more additional layer (film) areas, patterns, or structures may be formed therebetween. Therefore, the meanings should be judged according to the technical idea of the embodiment(s).

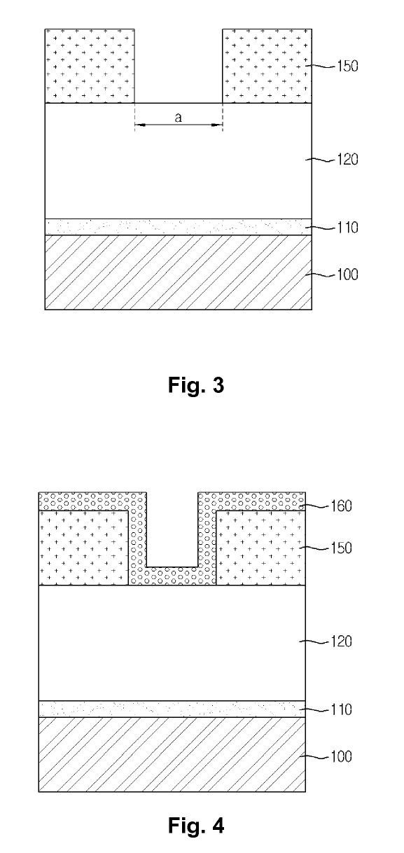

FIGS. 3 to 7 are sectional views illustrating an exemplary process of fabricating a semiconductor device according to embodiments of the invention.

As shown in FIG. 3, an etch stop layer 110 is formed on a semiconductor substrate 100, and a first insulation layer 120 is formed on the etch stop layer 110. The etch stop layer 110 may comprise or consist essentially of a nitride layer, such as a silicon nitride layer (SiN). The first insulation layer 120 may comprise or consist essentially of an oxide layer. For example, the first insulation layer 120 may comprise at least one member selected from the group consisting of BPSG (boro-phosphosilicate glass), TEOS (tetraethyl orthosilicate), USG (undoped silicate glass) and FSG (fluorine-doped silicate glass).

On the semiconductor substrate 100, memory devices, logic devices, and other components (which may be NMOS, PMOS, CMOS, analog, etc.) may be formed. Such devices may comprise various kinds of transistors, capacitors, metal wiring (e.g., resistors, inductors, capacitors), insulation layers, vias, via patterns and other electronic structures and/or devices.

A photoresist pattern 150 is formed on the first insulation layer 120. The photoresist pattern 150 exposes a given area of the first insulation layer 120. In detail, for a method of forming the photoresist pattern 150, a positive photoresist layer or negative photoresist layer may be formed on the first insulation layer 120.

Then, a bake process of the photoresist layer is performed to harden the photoresist layer. The photoresist may be baked at a temperature of from 150° C. to 200° C.

The photoresist layer is then selectively exposed.

A positive photoresist material includes material removed by a developing solution as a cross-linked portion 103b of the photoresist that receives light is broken. A negative photoresist material includes material in which a cross-linked is formed in the portion 103a receiving light and a portion not receiving light is removed by a developing solution. On the photoresist layer, the portion removed by such positive/negative characteristic exposes the insulation layer. The portion not removed by the developing solution remains on the insulation layer and becomes photoresist pattern 150.

A gap in a photoresist pattern or between adjacent photoresist patterns is called herein ‘a’. Here, an exposure apparatus to irradiate light to the photoresist layer may be a KrF exposure apparatus. The photoresist pattern 150 is formed using the KrF exposure apparatus, considering its exposure limits.

As shown in FIG. 4, a second insulation layer 160 is blanket-deposited onto the patterned photoresist 150, includes along the sidewalls of any gaps or openings in the photoresist. For example, the second insulation layer 160 may be formed on an entire face of the semiconductor substrate 100 on which the photoresist pattern 150 has been formed. The second insulation layer 160 may comprise a low temperature oxide (LTO) and be formed using a PECVD (plasma enhanced chemical vapor deposition) process at a deposition temperature lower than the bake temperature of the photoresist layer. The LTO may comprise a silicon oxide formed by PECVD using a silicon source (such as silane or TEOS) and an oxygen source (such as O₂ and/or O₃).

A thickness of the second insulation layer 160 may beneficially be smaller than a thickness of the photoresist pattern 150.

The second insulation layer 160 covers the photoresist pattern 150, and the photoresist pattern 150 is surrounded by the first and second insulation layers 120 and 160. That is, the second insulation layer 160 is also formed in a sidewall of the photoresist pattern 150, and thus, a gap between the photoresist patterns 150 (or an opening in photoresist pattern 150) becomes narrow after depositing the second insulation layer 160. Gap (a) in photoresist pattern 150 is narrowed by about twice the thickness of the second insulation layer 160 formed on the sidewall of the photoresist pattern 150.

The thickness of the second insulation layer 160 may differ according to a CD width and/or one or more process conditions of the contact hole being formed. For example, to reduce the contact hole by about 10 nm and meet margins for the upper CD width (a) to be formed by the photoresist pattern 150, the second insulation layer 160 may have a thickness of 100 Å to 150 Å. To reduce the contact hole by about 5 nm for the upper CD width (a) to be formed by the photoresist pattern 150, the thickness of the second insulation layer 160 may be 50 Å to 100 Å.

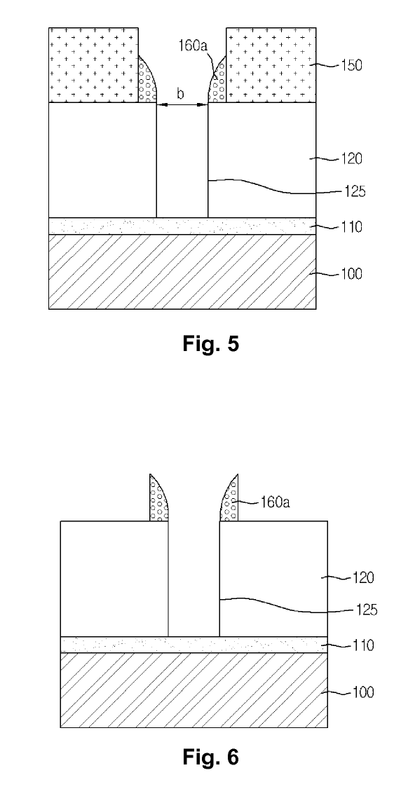

As shown in FIG. 5, the first insulation layer 120 is etched by a plasma etching, using the second insulation layer 160 and the photoresist pattern 150 as an etching mask. The plasma etching comprises dry etching, using a carbon and fluorine source (e.g., containing a gas of the formula CₓF_{y} where x and y are natural numbers, such as 1≦x≦5, and y=2× or 2x+2) and optionally, a noble gas such as Ar.

In the plasma etching, second insulation layer 160 formed in an opening in the photoresist pattern 150 (or between adjacent photoresist patterns 150) and first insulation layer 120 are etched, thereby forming a contact hole 125 in the first insulation layer 120. When the etch stop layer 110 under the first insulation layer 120 is exposed, the etching is stopped. Accordingly, a portion of the etching stop layer 110 is exposed to the contact hole 125 of the first insulation layer 120.

The plasma etching comprises anisotropic etching, and so the second insulation layer spacer 160a may be formed on a sidewall of the photoresist pattern 150. The second insulation layer spacer 160a serves as an etching mask, and thus, the first insulation layer 120 under the second insulation layer spacer 160a is scarcely etched if at all. As a result, a CD width (b) of the contact hole 125 formed in the first insulation layer 120 may be smaller than the gap or opening (a) in the photoresist pattern 150.

In describing embodiments of the invention, the photoresist pattern 150 is formed within an exposure limit range of the KrF apparatus, but the contact hole 125 actually may have in a finer (or smaller) size, exceeding the exposure limit range of the KrF apparatus. For example, if, in patterning lines, the KrF photolithography equipment has a lower limit of 150 nm, it is possible to form contact holes and/or other structures having a size or dimension of 140 nm or less (e.g. 130 nm or less, down to about 65-90 nm).

As illustrated in FIG. 6, after forming the contact hole 125 in the first insulation layer 120, an ashing process and a stripping process may be performed to remove photoresist pattern 150 and eliminate residual polymer, etc. The ashing process is to remove the photoresist pattern 150 and residual polymer within a dry etching chamber, and the stripping process is a cleaning process to remove remaining residual photoresist pattern 150 using a wet etching solution (e.g., a stripping solution containing sulphuric acid, such as 10-50% by weight or volume of concentrated H₂SO₄ in deionized water).

After the ashing process and the strip process are completed, a second insulation layer spacer 160a remains in the periphery of the contact hole 125 on the first insulation layer 120 having the contact hole 125.

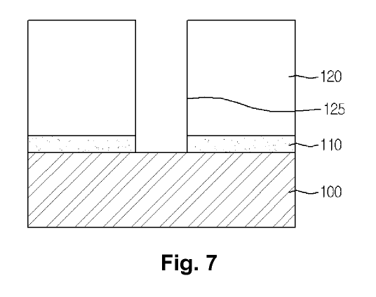

With reference to FIG. 7, the second insulation layer spacer 160a and the etch stop layer 110 exposed in a lower part of the contact hole 125 can be removed together using an etchback process. For example, the etchback process may be conducted on an entire face of the structure of FIG. 6.

As described above, according to embodiments of the invention, a contact hole with a finer width (e.g. below exposure limits) can be formed using a KrF exposure apparatus, and furthermore, contact resistance can be lowered, thereby improving device characteristics.

In addition, according to embodiments of the invention, process margins can be guaranteed using a KrF exposure apparatus of low price, and thus occurrence of defects is reduced, and manufacturing costs are lessened. Further, a research development and apparatus replacement expenses associated with ArF photolithography equipment can be saved, as it is not necessary to develop a new exposure process or use an ArF exposure apparatus of relatively high price.

Although a few embodiments of the present invention have been shown and described, it will be appreciated by those skilled in the art that changes might be made to the embodiments without departing from the principles and spirit of the invention, the scope of which is defined in the claims and their equivalents.

What is claimed is:

1. A method of fabricating a semiconductor device, comprising:
forming a first insulation layer on a substrate;
forming a photoresist pattern on the first insulation layer;
forming a second insulation layer covering the photoresist pattern;
forming a second insulation layer spacer on a sidewall of the photoresist pattern by etching the second insulation layer;
forming a contact hole by etching the first insulation layer using of the photoresist pattern and the second insulation layer spacer as a mask;
removing the photoresist pattern; and
removing the second insulation layer spacer.

2. The method of claim 1, wherein a diameter of the contact hole is smaller than a gap or opening in the photoresist pattern.

3. The method of claim 1, wherein the diameter of the contact hole is smaller than the gap or opening in the photoresist pattern by twice a width of the second insulation layer spacer.

4. The method of claim 1, wherein forming the second insulation layer on the sidewall of the photoresist pattern comprises anisotropic etching.

5. The method of claim 4, wherein the second insulation layer is anisotropically etched using a gas of the formula CₓF_{y}, where 1≦x≦5, and y=2× or 2x+2.

6. The method of claim 1, further comprising baking the photoresist pattern.

7. The method of claim 6, wherein the second insulation layer is deposited at a temperature lower than a baking temperature of the photoresist pattern.

8. The method of claim 1, wherein the first and second insulation layers each comprise an oxide layer.

9. The method of claim 1, wherein forming the contact hole comprises etching the first and second insulation layers using a plasma.

10. The method of claim 1, wherein removing the second insulation layer spacer comprises performing an etchback after the contact hole has been formed.

11. The method of claim 1, wherein the forming the photoresist pattern on the first insulation layer comprises:
forming a photoresist layer on the first insulation layer;
selectively exposing the photoresist layer using a KrF light source; and
developing the exposed photoresist layer.

12. The method of claim 11, further comprising baking the photoresist layer at a temperature of 150° C. to 200° C.

13. The method of claim 1, wherein the second insulation layer has a thickness of 100 Å to 150 Å.
